(19) United States
(12) Patent Application Publication
(10) Pub. No.: US 2005/0154567 A1
(43) Pub. Date: Jul. 14, 2005

(54) Three-dimensional microstructures

(75) Inventors: Rebecca J. Jackman, Boston, MA (US); Scott T. Brittain, Morrisville, NC (US); Olivier J.A. Schueller, Arlington, MA (US); Allan W. Adams, Menlo Park, CA (US); Hongkai Wu, Palo Alto, CA (US); Sue Hays Whitesides, Montreal (CA); George M. Whitesides, Newton, MA (US); Mara G. Prentiss, Belmont, MA (US)

Correspondence Address: Timothy J. Oyer, Ph.D.;Wolf, Greenfield & Sacks, P.C., 600 Atlantic Avenue, Boston, MA, 02210-2206, US

(73) Assignee: President and Fellows of Harvard College, Cambridge, MA (US)

(21) Appl. No.: 10/924,759

(22) Filed: Aug. 24, 2004

Related U.S. Application Data
(63) Continuation of application No. 09/593,716, filed on Jun. 14, 2000, now abandoned.
(60) Provisional application No. 60/140,177, filed on Jun. 18, 1999.
(60) Provisional application No. 60/141,184, filed on Jun. 25, 1999.

(51) Int. Cl. G06F 7/60; G06F 17/10; H01L 21/76

(52) U.S. Cl. 703/2

(57) ABSTRACT

The present invention relates to three-dimensional microstructures and methods for making these microstructures, particularly microstructures having integral features less than about 1 mm. Examples of these microstructures include trusses. The microstructures can be prepared from two-dimensional structures having a deformable portion. Thus, by applying a deformation along these deformable portions, e.g. bending, a third-dimension can be created. The deformable portions can comprise thinner dimensions than more rigid portions to allow facile deformation to a predetermined angle or orientation. Electroplating at least a portion of the three-dimensional microstructure with a metal coating allows the formation of integral features in addition to covering any defects formed by the deformation and/or strengthening any thin components. The initial two-dimensional microstructure can be prepared by various patterning methods such as soft lithographic methods.

### RELATED APPLICATIONS

This application is a continuation of U.S. application Ser. No. 09/593,716, filed Jun. 14, 2000, which claims the benefit under Title 35, U.S.C. § 119(e) of U.S. provisional application Ser. No. 60/140,177, filed Jun. 18, 1999, entitled “Three-Dimensional Microstructures,” by Rebecca J. Jackman et al., incorporated herein by reference, and of U.S. provisional application Ser. No. 60/141,184, filed Jun. 25, 1999, entitled “Three-Dimensional Microstructures,” by Rebecca J. Jackman et al., incorporated herein by reference.

### FIELD OF INVENTION

The present invention relates to three-dimensional microstructures and methods for forming these microstructures, particularly integral microstructures having components with dimensions less than 1 mm. The three-dimensional microstructures can be formed by applying deformations and/or electroplating to form integral connections.

### BACKGROUND OF THE INVENTION

Rapid growth in the area of microelectromechanical systems (MEMS) has created a demand for three-dimensional micron-scale components. Building microstructures in three dimensions presents significant challenges particularly when applying conventional photolithography techniques involving substrates having inherently planar geometries. Alternatives to photolithography for fabricating three-dimensional (3-D) structures typically include (1) serial patterning, i.e., depositing a series of layers on top of each other; or (2) carving, i.e. removing material from a block-like object in a stepwise manner. Approaches to MEMS fabrication that significantly depart from conventional lithography have been successful in “writing” 3-D structures in metals and polymers in serial fashion. These techniques include: UV stereolithography, laser-assisted chemical-vapor deposition (LCVD), localized electrochemical deposition, and laser micromachining. Although these methods may provide access to 3-D structures, they are often limited in the connectivities and intricacies of the structures that can be generated.

For large structures or macrostructures, well-established techniques exist for shaping metal components, such as casting, rolling, forging, stamping, grinding, milling, and cutting. Nuts and bolts, rivets, glue, and welding join these components. Performing most of these operations on micron-scale components can, however, prove to be difficult or impossible.

Most fabrication techniques used to make components for MEMS are derived from the microelectronics industry. These techniques can be grouped broadly into the categories of silicon micromachining and through-mask plating. Silicon micromachining involves photolithography to define patterns that can be transferred into silicon, and related materials, by standard techniques. 3-D structures can be prepared by these processes only by a layer-by-layer approach. Micromachining, thus, has several disadvantages: 1) it can pattern only a limited number of materials; 2) it can only form low-aspect-ratio planar structures with geometries that are determined by the crystallinity of the material; and 3) it requires facilities that limit accessibility and are not well suited to rapid prototyping. Through mask electroplating or LIGA (Lithographie, Galvanoformung, Abformung), involves lithography to define a mold in photoresist followed by electroplating to deposit metal (usually nickel) in the mold. The use of thick resists (<200 μm) exposed by collimated synchrotron radiation makes high-aspect-ratio structures possible, but variations in the third dimension are still difficult. In one case, 3-D structures have been achieved by use of an elaborate lathe that allows exposure on all sides of a resist-coated fiber. Limited access to synchrotron radiation, however, has resulted in the development of alternative schemes for generating high-aspect ratio molds in photoresist and other materials.

### SUMMARY OF THE INVENTION

One aspect of the present invention provides a method for making a three-dimensional microstructure comprising, conforming a first microstructure at a predetermined deformable portion.

Another aspect of the present invention provides a method for making a three-dimensional microstructure. The method involves deforming a microstructure at a predetermined deformable portion to provide a deformed portion. The deformed portion is then treated to form a non-deformable portion.

Another aspect of the present invention provides a method for making a three-dimensional microstructure involving providing a microstructure and deforming a portion of the microstructure in a first predetermined orientation to form a deformed portion. A deformed portion is then treated. A deformation is applied to a portion of the microstructure in a second predetermined orientation.

Another aspect of the present invention provides a method for making a microstructure having a chain-link. The method involves providing a first and a second three-dimensional substrate. A pattern is printed on the first and second substrates. The substrate is then supported adjacent the second substrate to provide a combined pattern having at least one feature resembling a link. The method further involves electroplating the supported first and second substrates followed by dissolving the first and second substrates.

Another aspect of the present invention provides a free-standing, integral three-dimensional truss.

Other advantages, novel features, and objects of the invention will become apparent from the following detailed description of the invention when considered in conjunction with the accompanying drawings, which are schematic and which are not intended to be drawn to scale. In the figures, each identical or nearly identical component that is illustrated in various figures is represented by a single numeral. For purposes of clarity, not every component is labeled in every figure, nor is every component of each embodiment of the invention shown where illustration is not necessary to allow those of ordinary skill in the art to understand the invention.

### BRIEF DESCRIPTION OF THE DRAWINGS

FIGS. 1a-1c show a patterned 2-D microstructure having deformable portions that can be folded into to form a tetrahedron, including a photocopy of a photomicrograph of the tetrahedron (1c);

FIGS. 2a-2e show a scheme for patterning a 2-D microstructure via microcontact printing;

FIGS. 3a-3e show a scheme for patterning a 2-D microstructure via photolithography;

FIG. 4 shows deformation of zig-zag lines of a 2-D microstructure to form a 3-D microstructure, including a photocopy of a photomicrograph of the 3-D microstructure;

FIGS. 5a-5g shows the use of two deformable portions to control the degree of bend of a cylindrical mesh, including a photocopy of a photomicrograph of the 3-D microstructure;

FIGS. 6a-6e shows the formation of a 3-D microstructure by applying axial stress and simultaneously deforming a plurality of deformable portions, including a photocopy of a photomicrograph of the 3-D microstructure;

FIGS. 7a-7g shows the formation of a 3-D microstructure having a chain link via two supporting substrates, including a photocopy of a photomicrograph of the 3-D microstructure;

FIGS. 8a-8e shows the formation of a 3-D microstructure having a trefoil know via two supporting substrates, including a photocopy of a photomicrograph of the 3-D microstructure;

FIGS. 9a-9c shows the formation of a 3-D truss having micron-scale thicknesses;

FIG. 10 shows (a) a photocopy of a photograph of a 3-D truss, (b) an expanded view of a photocopy of a photograph of the 3-D truss, (c) an SEM of a cross-section of the 3-D truss, highlighting the electroplated coating, including a photocopy of a photomicrograph of the 3-D microstructure; and

FIG. 11 shows (a) a 2-D pattern having designed mountain folds and valley folds, (b) a photocopy of a photograph of a resulting 3-D microstructure after applying the mountain folds, (c) a photocopy of a photograph of the final 3-D microstructure having an open framework after applying the valley folds.

### DETAILED DESCRIPTION

The present invention is directed to the preparation of 3-dimensional (3-D) microstructures through a variety of techniques such as soft lithography and microelectroplating. The 3-D microstructures can have very small components, i.e. in the micron-scale, while possessing stability and durability. These microstructures can be achieved without the need for tedious processes such as numerous layering steps or carving material from a solid object. Such 3-D microstructures have uses in MEMS where high-aspect ratio structures having intricate features are required. Examples of these microstructures include trusses and other open framework structures comprising slender, lightweight components which are capable of supporting objects many times its weight.

One aspect of the present invention provides a method for making a 3-dimensional microstructure. “Microstructures” as used herein, refers to a structure having at least one component with a dimension of less than about 1 mm, preferably less than about 500 μm, preferably less than about 100 μm, more preferably less than about 50 μm and even more preferably less than about 25 μm. A “component” refers to any discrete portion of the structure. For example, a ladder would have a number of components which include each rung and the two rods supporting each rung. The component can be planar, non-planar or curved. A dimension of the component can refer to at least any one of a height, width, length or diameter.

In one embodiment, a microstructure has at least about 50% of its components with at least one dimension of less than about 1 mm (i.e. microcomponents), preferably at least about 66% of its components with at least one dimension of less than about 1 mm, more preferably at least 75% of its components with at least one dimension of less than about 1 mm, more preferably at least about 90% of its components with at least one dimension of less than about 1 mm, even more preferably at least about 95% of its components with at least one dimension of less than about 1 mm, and even more preferably still at least about 99% of its components with a dimension of less than about 1 mm. In other embodiments, any of the recited percentages of components have a dimension less than any of the previously recited dimensions.

“3-dimensional microstructure” or “3-D microstructure” as used herein refers to a non-planar microstructure. A planar, or “2-D microstructure”, as used herein, refers to a structure having a substantially planar orientation with a height no more than 1/10 of the smaller of its width or length, preferably no more than 1/25 and more preferably no more than 1/50. In one embodiment, a 3-D microstructure refers to a structure having 3 dimensions in which the smallest dimension is at least 1/20 the larger of the other two dimensions.

In one embodiment, the method for making the 3-dimensional structure comprises providing a first microstructure and deforming that microstructure at a predetermined deformable portion. The first microstructure can be a 3-D microstructure. In one embodiment, the first microstructure is a two-dimensional (2-D) microstructure which can be deformed to make the 3-D microstructure. The 2-D microstructure can be formed by conventional lithography techniques.

“Deforming” refers to controlled manipulation of at least one portion of the first microstructure, preferably a predetermined deformable portion, to achieve a predetermined orientation. Examples of deforming include bending, unbending, folding, unfolding, twisting, untwisting or the like. Deforming does not include accidental deformations, which can result in an almost infinite number of orientations.

Typically, the “deformable portion” is structurally or mechanically weaker than surrounding portions and therefore will yield to force by bending, twisting. In one embodiment, the deformable portion has dimensions that are smaller than adjacent non-deformable portions. For example, an article can have a non-deformable portion that tapers to a relatively thin dimension. Applying a force to the deformable portion will result in a high likelihood of deformation at the area of the thin dimension while maintaining the original structure and orientation of the non-deformable portion. In one embodiment, the deformable portion has a smallest dimension which is less than about 50% that of adjacent, non-deformable portions. In other embodiments, the deformable portion has a smallest dimension which is less than about 40%, 30%, 20%, 10% and even as low as 5% the smallest dimension of adjacent nondeformable portions. Generally, the deformable portions comprise a malleable material such as a ductile metal that can be bent or folded easily. Deformable portions can also be created by providing a discontinuous pattern, i.e. a dotted line comprising segments of material alternating with segments of empty space. Alternatively, the deformable portion can be created by providing it with more degrees of freedom of movement than adjacent non-deformable portions. For example, a non-deformable portion can be structurally limited to a certain configuration or point in space with respect to the structure, whereas the deformable portion can be manipulated about with relative ease.

“Predetermined” refers to the capability to achieve a desired orientation. In one embodiment, the deformable portion allows deformation to a predetermined angle. In another embodiment, the deformable portion allows deformation at a predetermined direction. In another embodiment, the deformation can occur at both a predetermined direction and a predetermined angle.

In one embodiment, the 3-D microstructure is free-standing, i.e., it can exist in its 3-D configuration without support by a substrate or other supporting structure. The free-standing microstructure can be initially constructed on a supporting substrate but is capable of being released from the substrate. In another embodiment, the free-standing 3-D microstructure can be formed from without the need of a supporting substrate.

In one embodiment, the present invention features a 3-D microstructure having at least one microcomponent (having the micro-dimensions listed previously) integral with at least two other microcomponents in which the three components encompass three dimensions. “Integral” refers to any connection in which one component is welded, soldered, or otherwise permanently connected to the other such that disconnection of the two require fracture, i.e., not simply clipped, screwed, or attached by any other non-permanent process. Preferably, the integral connection is such that a point of attachment is not detectable either visibly or by any light microscopy technique. Thus, in this embodiment, an integral device incorporating an attachable microcomponent, such as a computer having a silicon chip.

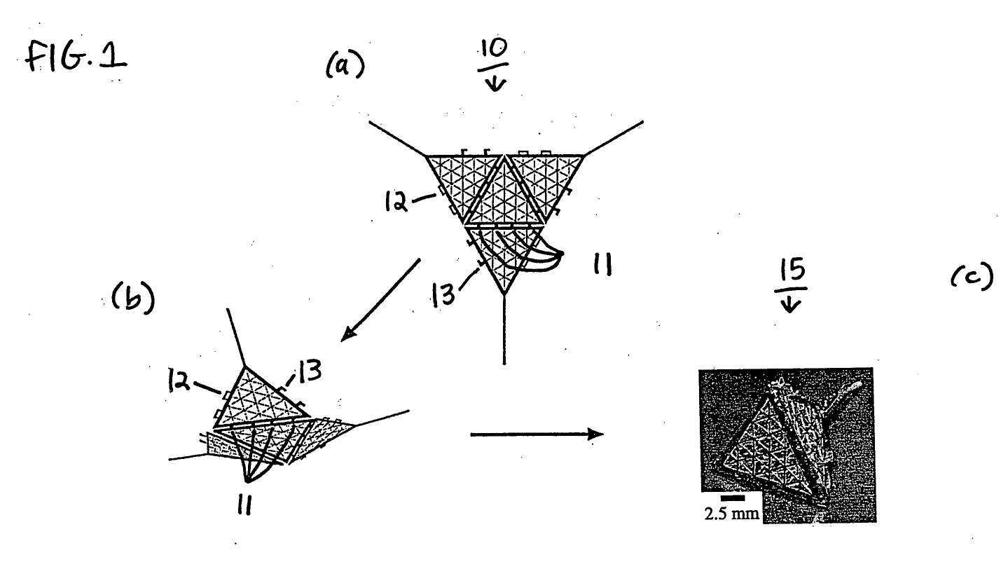

FIG. 1 shows an example of a 3-D microstructure of the present invention formed from a first microstructure having a predetermined deformable portion. In FIG. 1(a), first microstructure 10 comprises a free-standing 2-D microstructure that can be formed by any convenient technique, such as a patterning technique, e.g. lithography. Preferably the 2-D structure is formed by soft lithography techniques. “Soft lithography” involves surface patterning using non-traditional techniques as described in Xia et al., Angew. Chem., Int. Ed. Engl., Vol. 37, p. 550, 1998, which is incorporated herein by reference. Preferably, the parent invention involves the use of an elastomeric or flexible element in a pattern-transfer step, such as microcontact printing as described in International Patent Publication No. WO 96/29629, incorporated herein by reference. In one embodiment, the elastomeric element is an elastomeric stamp having a surface including a plurality of indentations formed therein defining an indentation pattern where the indentations are contiguous with a stamping surface defined in a stamping pattern. By coating the stamping surface with a patterning species, and contacting the stamping surface with a surface of a substrate, the pattern of the stamp is thereby transferred to the substrate surface. The patterning species can be a self-assembled monolayer as described in International Patent Publication No. WO 96/29629, referenced above.

FIG. 1(a) shows an example of a 2-D microstructure having predetermined deformable portions specifically designed to produce a 3-D tetrahedron microstructure. The deformable portions of structure 10 comprise a discontinuous pattern of a “dotted line” 11 having thin features (dark areas) alternating with gaps (unfilled areas). FIG. 1(b) illustrates deformation of structure 10 by folding structure 10 along dotted line 11.

In one embodiment, the 3-D microstructure can be maintained (i.e. held in place) by any non-permanent attachment, such as gluing, clipping, taping or the like. Referring back to FIG. 1(b), structure 10 further comprises slots 12 and hooks 13. A slot 12 meets a hook 13 upon folding structure 10, and hooks 13 can be inserted into slot 12 to hold the tetrahedron together. If an electrical connection at the point of attachment is desired, the non-permanent attachment can be provided by gluing with conducting epoxy or silver paint.

Metals that are easily patterned via soft lithography and then deformed may not provide sufficient structural integrity for all applications. For example, when a ductile metal such as silver or gold is folded, bent or otherwise deformed, the resulting structure may have cracks, small tears, or stress-thinned regions resulting around the area of deformation. Thus, in one embodiment, the method further comprises reinforcing the microstructure at least in the regions encompassing the deformed portions. Reinforcing allows these defects to be either covered or filled, and thus the mechanical integrity of the structure is retained and even enhanced. In alternative embodiment, the entire microstructure can be reinforced.

In one embodiment, the step of reinforcing comprises increasing the thickness of the structure by at least about 10%, more preferably by at least about 25%, more preferably by at least about 50% and even more preferably by at least about 100%. Of course, one of ordinary skill in the art can determine an appropriate thickness of coating such that the thickness can be increased by as much as 500%, 1000% or more. In one embodiment, the step of reinforcing involves coating at least the deformed regions with a material capable of conferring greater stability or rigidity to the 3-D microstructure. The reinforcing material can be the same or a different material from the initially deformed microstructure.

In one embodiment, the 3-D microstructure is reinforced by plating with a metal. Examples of metal plating processes include electroless plating and electroplating. “Electroplating” refers to a process involving exposing at least a portion of an article to a solution containing metal ions and subjecting the portion of the article and solution to electrochemical conditions. In one embodiment, at least a portion of the article is immersed in the solution, and preferably at least the deformed portion is immersed. Electrochemical conditions involve the application of an electrical current resulting in a transformation (e.g. reduction) of metal ions to metal atoms. The resulting metal atoms can be deposited onto the article as a metal coating formed around the immersed article portion.

When electroplating, a thickness of the metal coating can be manipulated by certain factors such as concentration of the metal ions in solution, electroplating time and/or current density. The electroplated metal can be selected from any metal capable of being electroplated, i.e. the metal can exist as a stable solution of metal ions and subjected to electrochemical conditions to form the neutrally charged metal. Examples of such metals include nickel, silver, etc. Electroplating can be considered a method of “electrochemical welding” to provide a final product having high structural integrity.

Prior to the step of reinforcing, the structure can be fastened, attached or held in place in a non-permanent manner, as described previously. Non-permanent attachments allow the structure to maintain its form for the duration of the reinforcing step. Where the reinforcing comprises electroplating, the non-permanent attachment is capable of withstanding solution and/or electrochemical conditions.

FIG. 1(c) shows the results of an example of the method of the present invention, comprising the steps of folding structure 10 to form a tetrahedron, non-permanently attaching the tetrahedron by inserting hooks 13 into slots 12 and immersing the entire tetrahedron into an electroplating solution to form an entirely integral tetrahedron 15. Of course, the tetrahedron could have been partially immersed in the electroplating solution to electroplated only the points of connection of slots 12 and hooks 13. Thus, a corner of tetrahedron 15 comprises three components in each of three dimensions, where the three components are integral with one another. For certain structures, partial electroplating may be sufficient with the benefit of cost and time savings. Plating can be used in fabrication of 2-D microstructures which are later deformed into 3-D microstructures.

Electroplating can be considered as a method of “electrochemical welding.” An advantageous feature of the method of electrochemical welding lies in the capability to make integral connections between several points at the same time. Thus, one embodiment of the present invention involves a method for simultaneously making a plurality of at least two integral connections to form a 3-dimensional microstructure. An additional advantageous feature involves the added benefit of also simultaneously coating other portions of the structure not involved in the formation of integral connections, such that a microstructure having thicker dimensions is readily obtained to confer structural stability to the microstrcuture.

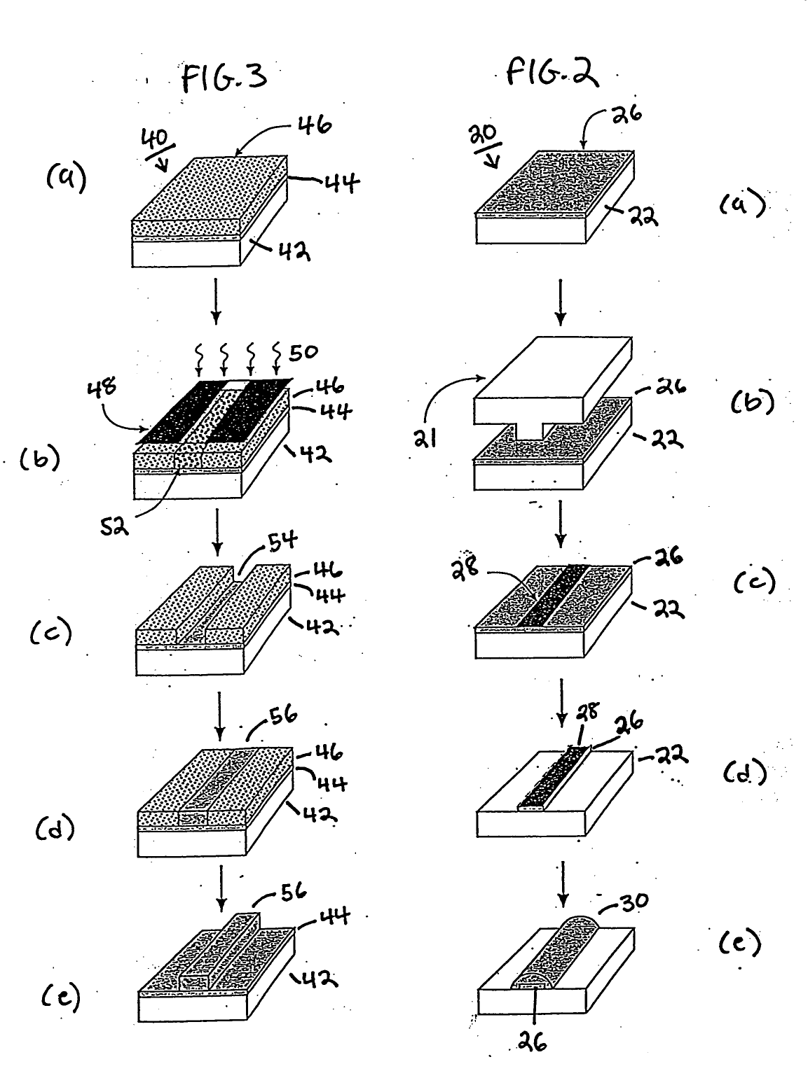

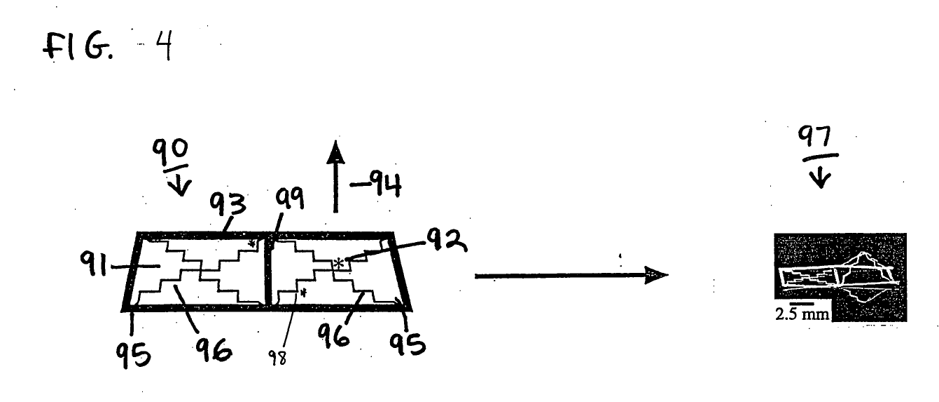

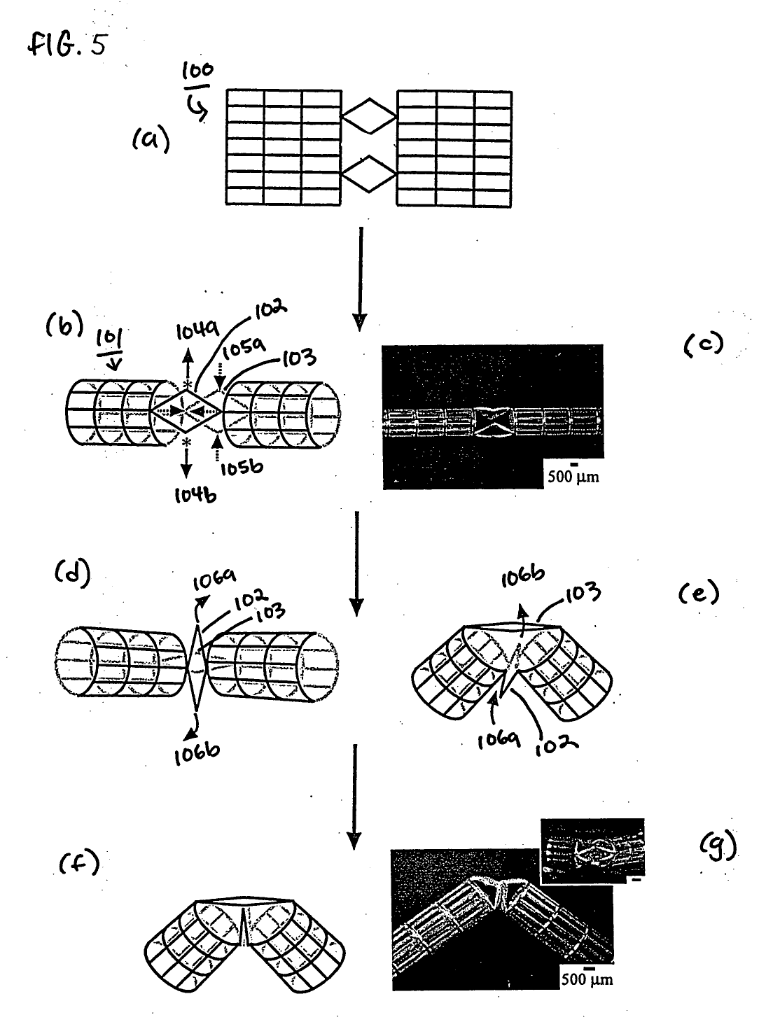

FIGS. 2 and 3 show examples of one technique to provide patterned 2-D microstructures. FIG. 2(a) shows article 20 comprising a silicon substrate 22 having a silver layer 26 positioned on silicon substrate 22. An adhesion promoter such as a layer of titanium can be positioned between substrate 22 and silver layer 26. In FIG. 2(b), an elastomeric stamp 21 having a surface defining a predetermined pattern is coated with a self-assembled monolayer (SAM) of hexadecanethiol, and the predetermined pattern can be transferred from the stamp 21 onto silver layer 26, to provide a pattern of SAM 28 (FIG. 2(c)). Exposing article 20 to a wet chemical etch causes removal of the non-patterned portions of silver layer 26 resulting in silver layer 26 being protected by SAM layer 28 in a pattern dictated by the elastomeric stamp 21 (FIG. 2(d)). FIG. 2(e) schematically shows the result of electroplating the patterned silver 26 to produce a coating 30 around silver layer 26. The coating can be a metal such as nickel.

FIG. 3 shows another example of patterning to form the first microstructure. FIG. 3(a) shows an article 40 having a silicon substrate 42 coated with a silver layer 44 which is further coated by photoresist layer 46. An intermediate layer of adhesion promoter, such as a layer of titanium, can be positioned between substrate 42 and silver layer 44. In FIG. 3(b), a photomask 48 having a predetermined pattern is positioned over photoresist 46 such that there is an exposed portion 52 of the photoresist. Article 40 is then subjected to electromagnetic radiation 50. Upon development of the photoresist the exposed portion 52 is removed, creating gap 54 (FIG. 3(c)). Gap 54 can be subjected to electrochemical conditions to result in deposition of an electroplated layer 56 (FIG. 3(d)). FIG. 3(e) shows a final patterned electroplated layer 56 supported by silver layer 44, upon dissolution of the photoresist.

From FIGS. 2 and 3, it can be seen that the first microstructure can initially be formed on a supporting substrate. In one embodiment, deformation can be applied to the first microstructure while the first microstructure is supported. In another embodiment, the first microstructure is capable of being released from the substrate prior to deformation. For example, where the first microstructure is nickel, release from the substrate can be achieved by immersion of the article in an HF solution (e.g., 12% HF), where the substrate is SiO₂ to dissolve the substrate. In one embodiment, the portion of the microstructure supported by a substrate is capable of being released from the substrate.

In one embodiment, the present invention provides a method for making a 3-D microstructure comprising connecting a first microstructure to a second microstructure. In this aspect is the resulting 3-D microstructure involves the first microstructure being integral with the second microstructure. An advantageous feature is that the resulting integral connection confers rigidity and structural integrity to the 3-D microstructure. The first microstructure is preferably not supported by a substrate whereas the second microstructure can either be supported by a substrate or can also be free-standing.

In one embodiment, connecting the two microstructures to form an integral connection is accomplished by reinforcing technique such as coating. In one embodiment, the coating step involves electroplating.

Another aspect of the present invention provides a method for making a 3-D microstructure involving deforming a microstructure at a predetermined deformable portion to provide a deformed portion. This deformed portion is then treated to form a non-deformable portion. In one embodiment, the treating involves electroplating the deformed portion. In this manner, the once deformable portion, can be rendered sufficiently non-deformable.

Thus, reinforcing (e.g. electroplating) the folded structure thus can serve three functions: (1) providing thicker metal features where desired; (2) providing an integral connection; (3) covering any cracks or defects resulting from the deformation; and (4) rendering deformable portions non-deformable.

FIG. 4 shows another example of a deformable portion having a predetermined deformation in a desired direction. In FIG. 4, first microstructure 90 is a planar structure comprising a rigid (non-deformable) rectangular outline 93 divided in half width-wise by a rigid dividing line 99 to provide two adjacent squares having eight inner corners 95. Each corner 95 is connected to a diagonally opposite corner 95 by a zig-zag line 96. Zig-zag line 96 is thinner than rigid outline 98 or dividing line 99, rendering zig-zag line 96 capable of the deformation. Each zig-zag line 96 intersects another zig-zag line 96 at point 92, which represents one type of a predetermined deformable portion in FIG. 4. Other deformable portions include connections between rigid portions 93 and thinner portions 96, and apexes 98 of zig-zag lines 96. Examples of the different types of deformable portions are indicated in FIG. 4 with an asterisk (*).

By bending portion 92 out of the plane in a direction indicated by arrow 94, a 3-dimensional microstructure 97 can be achieved. Although it may be possible to bend deformable portion 92 in several directions other than arrow 94, the most stable orientation is achieved when portion 92 is bent in the direction of arrow 94 to the extent that all zig-zag lines 96 are straightened equivalently. Thus, deformable portion 92 is intended to be deformed in a predetermined direction. Should it be desired that deformable portion 92 be directed towards another direction, the dimensions of zig-zag lines 96 can be altered, such as by changing the length of each straight-line portion of zig-zag line 96 or the points of intersection of two zig-zag lines 96, to achieve the most stable configuration in the other direction. It is understood that portion 92 can be deformed in the direction of arrow 94 to a variety of heights. For example, a small deformation of portion 92 will result in a smaller height than a larger deformation. The extent of deformation can also be predetermined by varying the dimensions of zig-zag lines 96 (i.e., changing the length of straight line portions of the zig-zag line 96).

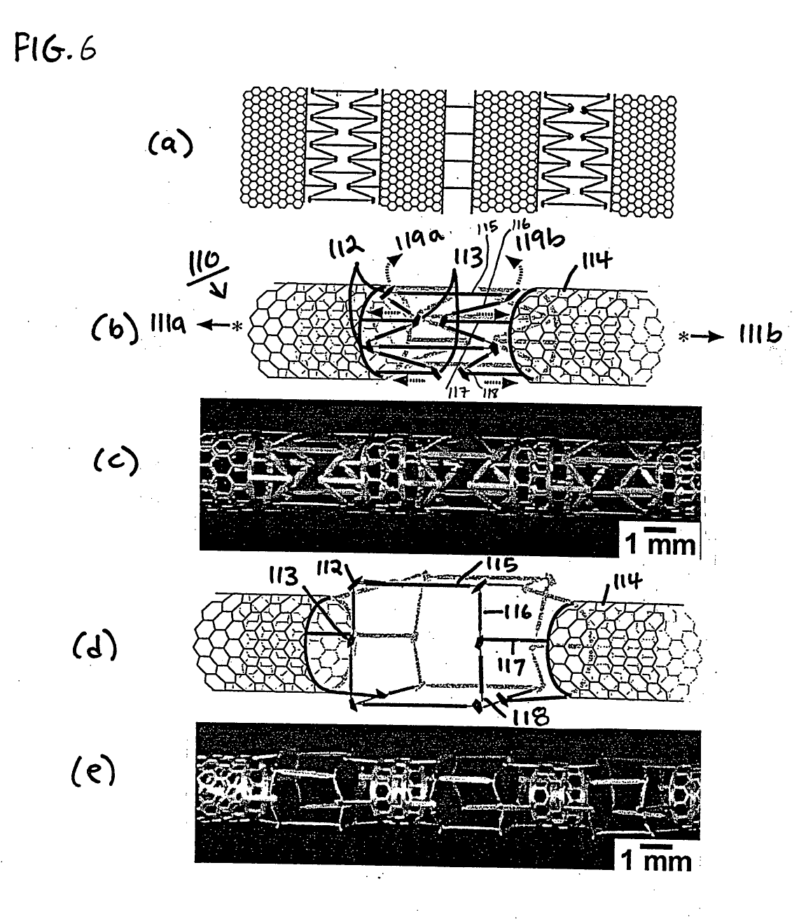

Use of deformable portions allow the remaining portions to retain their structural integrity. For example, it is known that bending a rigid mesh cylinder typically results in collapse of the open mesh framework, at least in the regions in the vicinity of the bend. FIG. 5(b) shows a cylindrical mesh structure 101 interrupted by diamond-shaped deformable portions 102 and 103. FIG. 5 also illustrates how more than one deformable portion allows greater control over the extent of deformation. If structure 101 contained only one diamond-shaped deformable portion, the structure could bend without collapse of the framework but there would be little control over the degree and orientation of bending. By positioning two diamond-shaped deformable portions 102 and 103 on opposite sides of the structure 101, a designed bend of at least 90° can be introduced. Referring to FIG. 5(d), as structure 101 is deformed manually by moving two vertices of diamond 102 (vertices marked with an *) in the direction of arrows 104a and 104b, two vertices of diamond 103 will tend to move inward in response in a direction indicated by arrows 105a and 105b. At the most extreme bend angle, as shown in FIGS. 5(d) and 5(e), diamonds 102 and 103 collapse to form an approximate linear portion. Upon achieving the linear portion, structure 101 cannot bend further in the same direction.

To achieve further structural stability, protruding points of diamond 102 can be bent in the direction of arrows 106a and 106b, to result in the structure shown in FIG. 5(f). The deformed portions 102 and 103 can then be reinforced to render these portions non-deformable. A copy of photographs of the cylindrical structure before and after deformation followed by electroplating is provided in FIGS. 5(c) and 5(g), respectively.

The cylindrical structures of FIG. 5(b) can be achieved by creative design of the first microstructure. For example, all cylindrical patterns can unfold onto a planar surface, and thus the first microstructure can be a 2-D microstructure. FIG. 5(a) shows a pattern of a planar pattern 100 that can be used to form a cylindrical surface of structure 101 (FIG. 1(b)) having diamond-shaped deformable portions (using soft lithographic techniques as described above with reference to FIGS. 2 and 3).

Thus, the methods of the present invention can be used to prepare 3-D structures which cannot be achieved by conventional two-dimensional lithography techniques. However, the initial microstructures can be provided by various patterning methods.

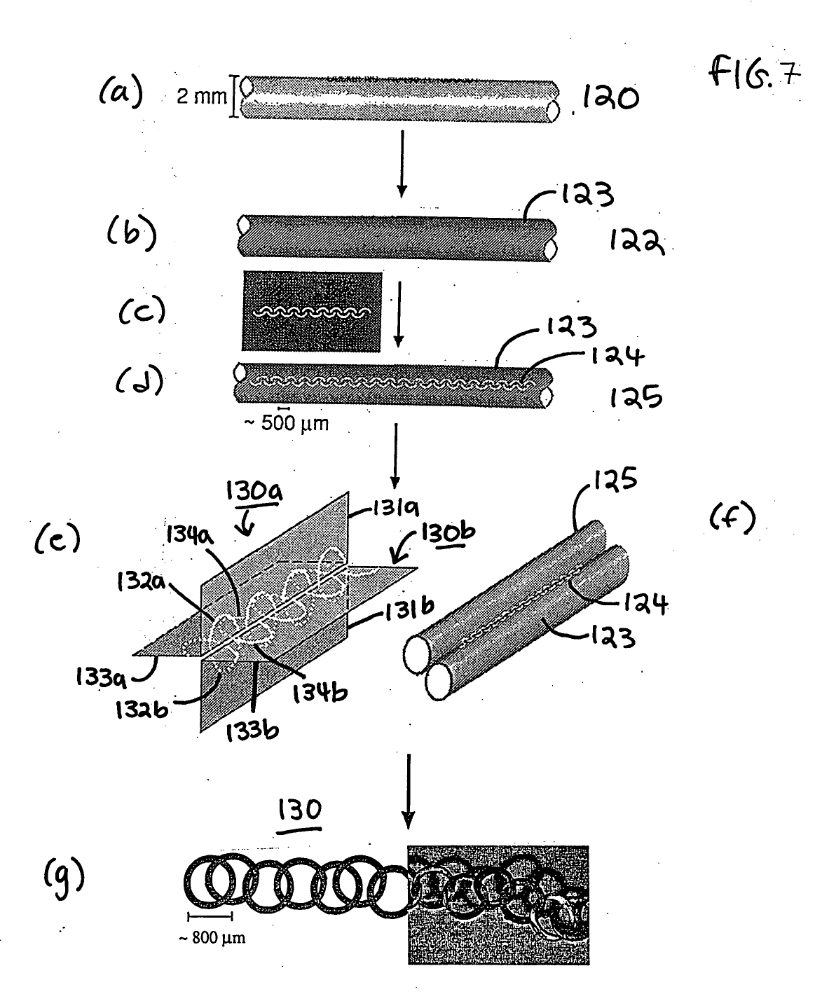

In one embodiment, a concerted deforming mechanism involving a plurality of deformable portions can provide 3-D microstructures having resulting rigid deformed portions, without the need for further reinforcement. For example, FIG. 6(b) shows open mesh cylindrical structure 110, having a plurality of deformable portions of types 112 and 113. By applying an axial stress in the direction of arrows 111a and 111b, portions 112 and 113 deform to form a cuboid structure as shown in FIG. 6(d). The cylindrical mesh wires 114, are constructed to be sufficiently rigid such that deformations of mesh wires 114 do not occur during application of the axial stress. In addition, the cuboid in FIG. 6(d) also includes portions that do not deform, i.e., straight line portions 115-117. The non-deforming properties arise because portions 115-117 are thicker than deformable portions 112 and 113, as provided by very thin straight line portion 118 which are part of deformable portions 112 and 113. An angle formed by points 113-112-113 in FIG. 6(b) would depend on factors such as the length of the region encompassing all the deformable portions, or the positioning of portion 113. Such features need to be contemplated during design of the initial planar pattern which is shown in FIG. 6(a).

FIGS. 6(c) and 6(e) show copies of photomicrographs of structure 110 before and after deformation, respectively. The cylinder can include alternating sections of deformable portions and cylindrical mesh units throughout the length of the structure 110. The deformable portion does not necessarily need to result in a cuboid structure, as many other geometries that provide rigid structures can be envisioned.

In the structures of FIGS. 5 and 6, any number of deformable portions can be applied along the length of the cylinder. In addition, each cylinder can include a variety of deformable portions. For example, in FIG. 5, a cylinder 101 which contains a number of deformable portions where each deformable portion is alternated with a cylindrical portion, results in an overall closed, circular geometry after applying the deformation. The relative positioning of adjacent pairs of diamonds can control the relative orientations of the rigid mesh portions. Should each pair of diamonds be rotated slightly with respect to adjacent pairs of diamonds, a helical structure would result after deformation.

Another aspect of the present invention provides a method for making a microstructure having a link. A link can be constructed by providing a hollow portion and a component penetrating the hollow portion. In one embodiment, the hollow portion is contained within an outline of a closed shape. The closed shape can be a regular shape such as a triangle, a circle, an oval, a rectangle, an octagon. Alternatively, the closed shape can be irregular.

The component penetrating the hollow portion links the outline of the closed shape. The link can be detachable e.g. a rod penetrating a hoop is linked to the hoop but can be withdrawn from the hoop to break the link. The component penetrating the hollow portion can be straight, curved, planar, three-dimensional, or the like, so long as it is of a sufficient dimension to fully penetrate the hollow portion. The component penetrating the hollow portion can be non-detachable, e.g. a chain link. A chain link comprises two components fastened two each other, yet each are freely movable. Thus, the component penetrating the hollow portion can also comprise an outline of a closed shape having any of the features described previously.

In this aspect, the method involves patterning a link by providing first and second 3-D substrates, each substrate having a pattern printed thereon. The pattern on each substrate is designed such that upon supporting the first substrate adjacent the second substrate, the combined pattern has at least one feature resembling a link. In one embodiment, the first and second substrates are non-planar, e.g. curved or contain a fold.

The supported first and second substrates can be electroplated, and upon dissolving the first and second substrates, the chain-link results.

FIG. 7 shows an example of a method for making a chain-link structure shown in FIG. 7(g). FIG. 7(e) schematically illustrates how a chain-link structure is accessible through the use of two substrates. Each substrate 130a and 130b comprise two planar faces positioned adjacent each other via an outside edge to form a 90° angle, i.e. vertical faces 131a and 131b and horizontal faces 133a and 133b. 3-D substrates 130a and 130b each have a 3-D (i.e., non-planar) pattern printed on each face, i.e. the pattern is continuous from a vertical face through to a horizontal face. Substrate 130a includes a semicircle 132a on face vertical face 131a having a complementary semicircle partner 132b printed on horizontal face 133b of substrate 130b. Substrates 130a and 130b can be oriented relative to each other such that complementary semicircles 132a and 132b form a whole circle.

A chain link is designed by patterning semicircles 134a and 134b on faces 133a and 133b of respective substrates 130a and 130b where a portion of semicircles 134a and 134b penetrate the whole circle (hollow portion) of complementary semicircles 132a and 132b. Thus, a whole circle formed by matched semicircles 134a and 134b function as the component that penetrates the hollow portion formed by whole circle 132a and 132b. The component does not necessarily need to be a whole circle to penetrate a hollow portion and can be any closed geometrical shape, an open circle having a small gap, a straight line portion etc.

It has been discovered that alignment is achieved easily by using non-planar substrates such as cylindrical substrates in place of block-like substrates 130a and 130b. In FIG. 7(a) a glass capillary 120 is provided. The capillary 120 is coated with a photoresist layer 123 to provide capillary 122 (FIG. 7(b)). Printing a pattern 124 of alternating semicircles can be achieved with the use of a flexible photomask, the design of the photomask being shown in FIG. 7(c) to result in patterned capillary 125 (FIG. 7(d)). FIG. 7(f) shows two capillaries 125 positioned in a manner to allow matching of the appropriate semicircles, analogous to the example of FIG. 7(e). The supported substrates are then subjected to an electroplating bath, to electroplate the areas defined by pattern 124. Upon dissolving the photoresist layer 123 and the glass, chain-link structure 130 results, as shown in FIG. 7(g).

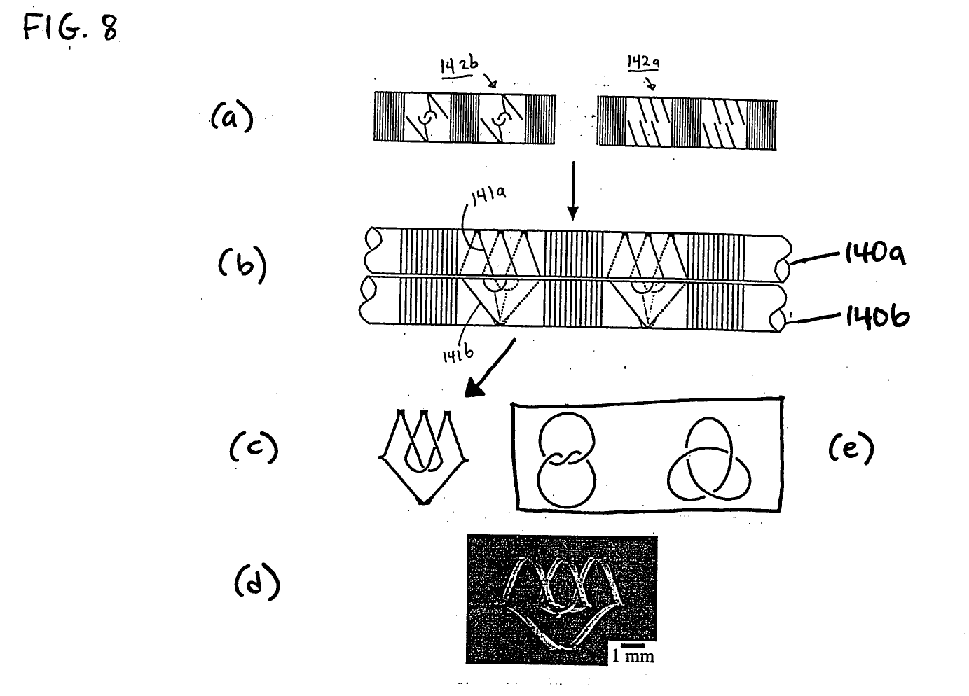

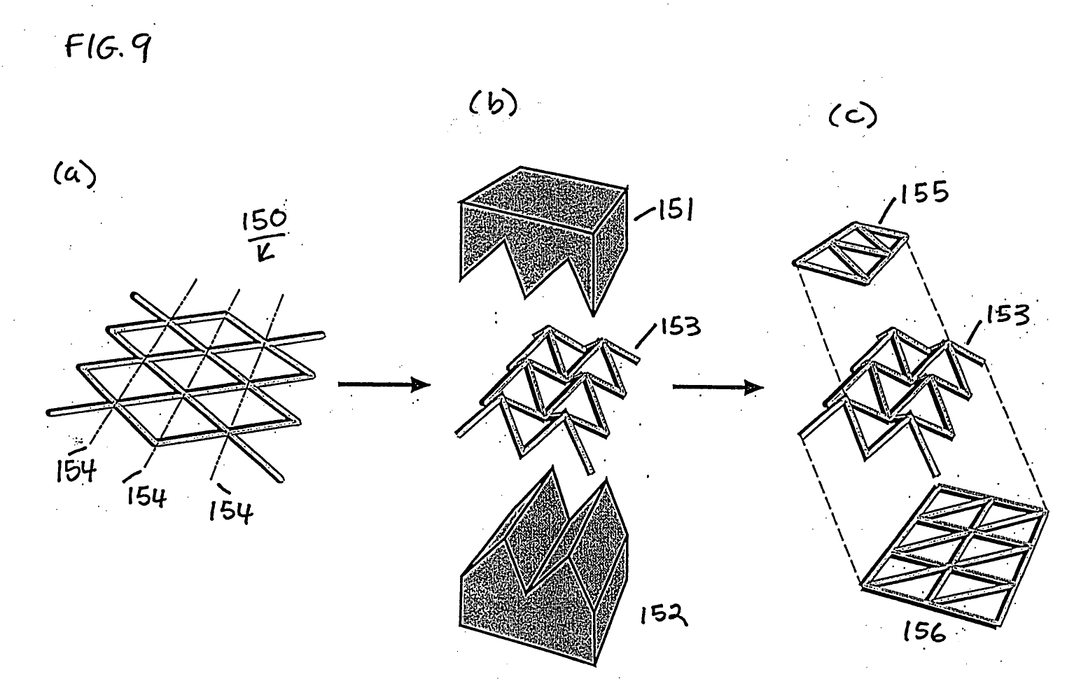

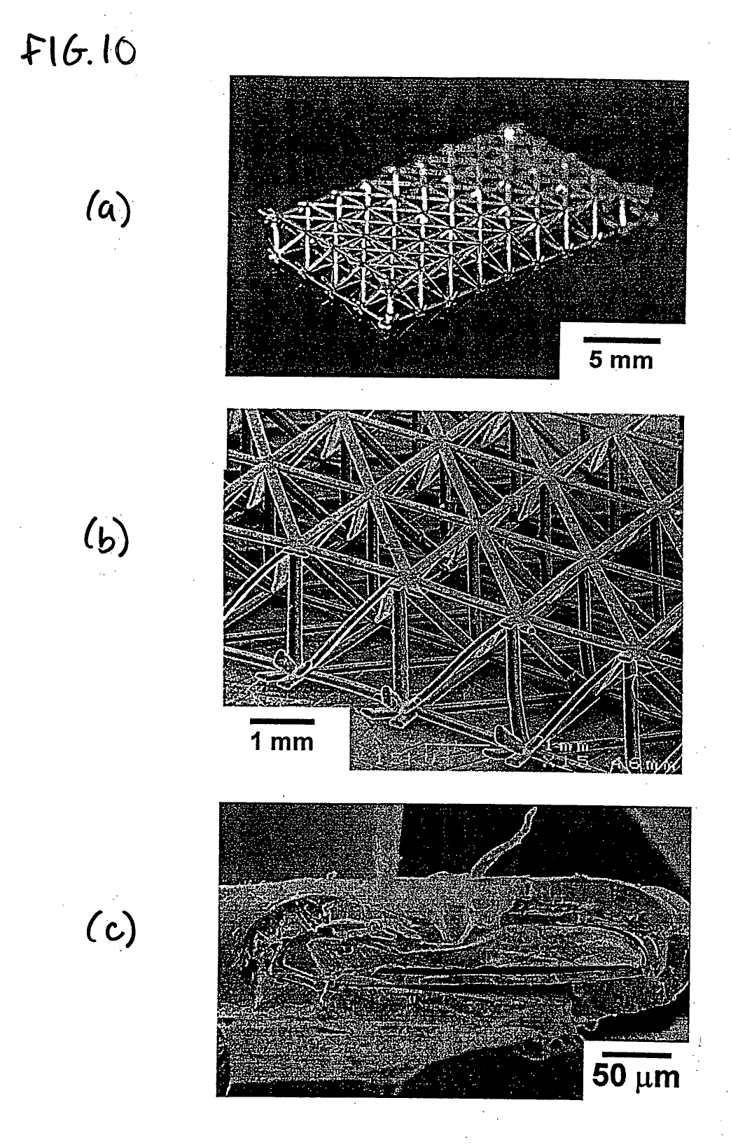

From these basic principles for preparing chain-link structures, more intricate intertwined structures can be achieved by appropriate design of the photomask for each substrate. FIG. 8 schematically shows the preparation of a single knotted loop (e.g., a trefoil knot). FIG. 8(a) shows the 2-D designs 142a and 142b of the photomask for complementary substrates 140a and 140b, shown in FIG. 8(b). Substrates 140 can be cylindrical, and can be a glass capillary coated with a photoresist as similarly discussed for the substrates of FIG. 7. By patterning substrates 140a and 140b with patterns 141a and 141b, and subjecting the supported substrates to an electroplating bath followed by dissolution of the photoresist and glass capillaries, a trefoil knot results as shown in FIG. 8(c). A photograph of the trefoil knot is shown in FIG. 8(d). FIG. 8(e) shows further examples of other complex intertwined structures that can be produced by this method.

Another aspect of the invention provides a free-standing 3-dimensional truss. “Truss” refers to a structure having an open framework capable of supporting an object at least 2, 3, 5 or even 10 or more times its weight. In one embodiment, the truss comprises an open framework and has at least one dimension less than about 1 mm. Open framework structures have advantageous properties of rigidity and stability while using a minimal amount of material. Trusses can be either two-dimensional or three-dimensional. Macroscopic trusses are found in many building components. 2-D trusses are often used as roof supports whereas 3-D trusses can be found in the ceiling of a gymnasium, cylindrical vaults and hemispherical domes. A 2-D truss takes advantage of the inherent stability of triangles where angles of a triangle cannot changed without changing the lengths of its sides. Because a truss is based on triangular shapes, elements of a truss are relatively slender and widely spaced, allowing trusses to retain a high strength-to-weight ratio. 3-D trusses utilize either a tetrahedron as the basis of the open framework where a tetrahedron comprises four triangles, or a square pyramid comprising four triangles arising from a square base.

In one embodiment, the 3-D truss comprises at least two tetrahedra placed side-by-side. “Side-by-side” can involve aligning two edges of the tetrahedra together or aligning two faces of the tetrahedra together. In another embodiment, the 3-D truss comprises at least two square pyramids placed side-by-side.

The techniques to build macroscopic trusses are not applicable at the micron scale. Macroscopic trusses utilize a large number of individually machine components, such as nuts, bolts and welding. Trusses are often made of steel components, and the process to produce steel components, such as rolling, casting and forging are not feasible at scales of less than 1 mm.

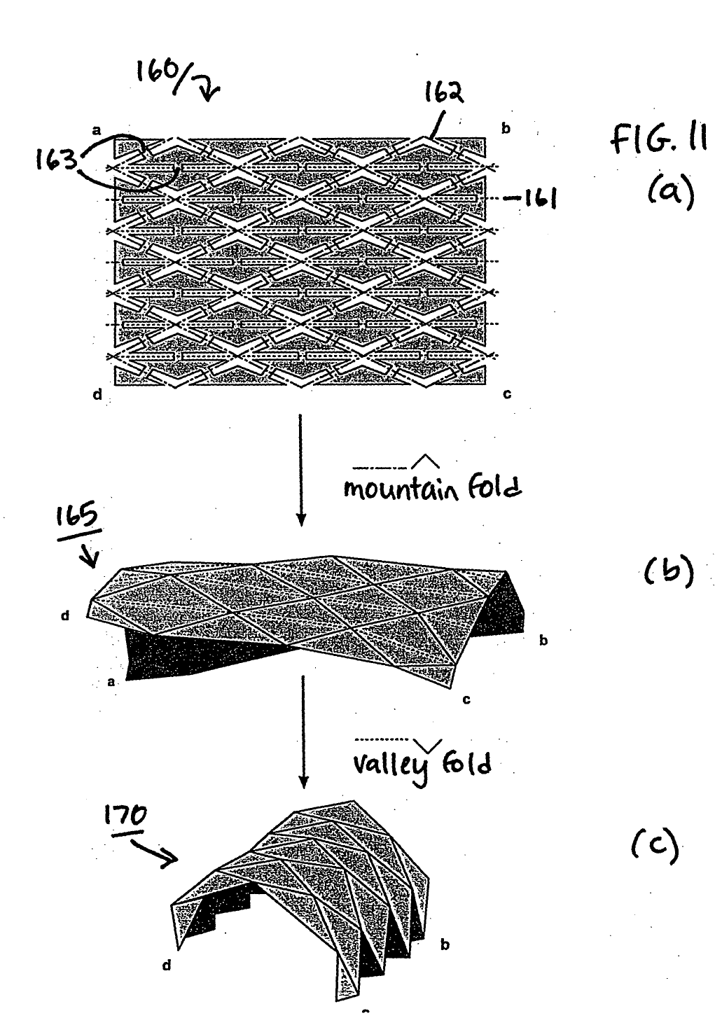

This aspect of the present invention to prepare trusses can be accomplished by using several techniques described previously. FIG. 9 shows an example of preparing a truss of the present invention. In FIG. 9(a), a 2-D pattern 150 is prepared by microcontact printing methods as described in FIG. 2. Typically, the truss comprises a malleable metal such as silver. This 2-dimensional structure 150 can be electroplated in a silver solution to provide a thicker silver layer. In FIG. 9(b), the structure 150 is folded along lines 154 to form a 3-D framework based on a square pyramid structure. The folding can be achieved by the use of a brass dye, having parts 151 and 152 to achieve the folded structure 153. In FIG. 9(c), folded structure 153 can be assembled with square grids 155 and 156 that function as the square base of the square pyramid. Both grids can be prepared by the patterning techniques used to prepare the structure 150 in FIG. 9(a). The grids can be attached temporarily with the use of silver paint, and an integral connection can be achieved by electroplating the entire assembly.

FIG. 10(a) shows a photomicrograph of the completed truss and FIG. 10(b) shows an expanded view of the truss. FIG. 10(c) shows an SEM image of the truss, highlighting the integral connection of the joints.

FIG. 11 shows another example of an open framework of the present invention. FIG. 11(c) shows an open framework microstructure 170 based on triangular features where the overall shape of the microstructure 170 is an approximate half cylinder. Microstructure 170 has a hollow inner core that provides “openness” of the framework. Microstructure 170 can be formed from 2-D structure 160 having corners a, b, c and d shown in FIG. 11(a), which can be achieved by patterning techniques as described previously. Forming the approximate half cylinder shape requires a sequence of several designed folds of deformable portions having discontinuous patterns. A “mountain” fold, or an upward fold is applied along long-dashed lines 162, whereas a “valley” fold, or a downward fold is applied along short dashed lines 161. FIG. 11(b) shows a resulting 3-D microstructure 165 after applying a series of mountain folds and indicating the locations of corners a, b, c and d. FIG. 11(c) shows the final 3-D microstructure 170 having an open framework after applying a series of valley folds to microstructure 165. Changing a variety of parameters, such as length of triangle sides, the angles of the triangles, and combinations of mountain and valley folds can provide various types of open framework structures. As with the trusses, these frameworks provide great stability and can span a large space. To achieve the integrity of the folds, the structure can be electroplated to cover either defects resulting from the folds or increase the thickness of the deformable portions that define the folding points.

The function and advantage of these and other embodiments of the present invention will be more fully understood from the examples below. The following examples are intended to illustrate the benefits of the present invention, but do not exemplify the full scope of the invention.

### EXAMPLE 1

Referring to FIG. 1, 2-D microstructure 10 was fabricated by microcontact printing and wet etching of a silver film, followed by electroplating the 2-D microstructure with nickel. Dissolution of a sacrificial SiO₂ layer (not shown) with aqueous HF released the microstructure 10 from the silicon substrate. Manual folding of the grid resulted in a tetrahedral structure. A system of slots 12 and hooks 13 held adjacent edges in close contact during a final electrochemical welding step to form final 3-D microstructure 15.

### EXAMPLE 2

Described in this Example is a transformation of a planar structure into a 3-D microstructure of FIG. 4 by controlled deformation. A self-supporting, 2-D microstructure 90 was formed by microcontact printing, followed by etching, then electrodeposition, and, finally, release from the substrate. Thin, zigzag lines 96 were designed to deform (straighten) whereas the thicker, square outline 93 and dividing line 99 were designed to withstand deformation and maintain a square base. The optical micrograph of resulting 3-D microstructure 97 shows an undeformed, 2-D metallic microstructure and a similar structure after the out-of-plane deformation. The deformation produced a square-based pyramidal structure. Further electroplating increased the structural integrity of the 3-D microstructure.

### EXAMPLE 3

Described in this Example is a deformation of free-standing cylindrical microstructure 101 of FIG. 5 to produce a noncylindrical structure of FIG. 5(g). The 3-D microstructure was formed by microcontact printing on silver-coated glass capillaries (˜2 mm diameter), followed by wet-chemical etching to remove the silver that remained underivatized after printing, electroplating to increase the rigidity of the structure, and finally dissolution of the glass to produce a free-standing structure.

### EXAMPLE 4

Described in this Example is a schematic illustration of the fabrication of 3-D microstructure of FIG. 6 formed by deformation of a cylindrical mesh 110 under tension. Using an electron beam evaporator, glass capillaries (˜2 mm diameter) were coated with titanium (˜25 Å; adhesion promoter) and silver (˜500 Å). Two orthogonally rotating stages ensured that the capillaries were evenly metallized around their circumference. Microcontact printing of hexadecanethiol with an elastomeric stamp formed a patterned self-assembled monolayer on the capillary. The dimensions and angles of the wires that form the cube were adjusted relative to the circumference of the cylinder: for a cube with edges of length d formed on a cylinder with a diameter, d, the edge of the cube was set equal to d, the components of the edges were of length d/2 and were oriented at an angle of 52° to the edge. Immersion for 15 to 30 s in an aqueous ferricyanide bath (0.001 M K₄Fe(CN)₆, 0.01 M K₃Fe(CN)₆, 0.1 M Na₂S₂O₃) removed the underivatized silver and ˜10 s in 1% HF solution removed the exposed titanium. A conductive metal pattern was formed in the design of the stamp of FIG. 6(a). Electroplating a thin (˜20 μm) layer of silver from a plating bath held at room temperature (Technic, Providence, R.I., Techni-Silver E2) at a current density of ˜20 mA/cm² increased the rigidity of the structure. The area of the pattern was estimated by measuring the total area spanned by the pattern and then calculating, based on the design, the percentage of the area covered by metal. Dissolution of the underlying glass substrate in HF produced a free-standing mesh. (Caution: direct exposure of skin to concentrated, aqueous HF can damage skin and bones.) The final cube formed when the mesh was expanded under tension by pulling on both ends of the structure with tweezers. Further electroplating reinforced the structure and made it rigid.

### EXAMPLE 5

Described in this Example is a scheme for fabricating a chain-link using a flexible photomask and electrochemical welding, as shown in FIG. 7. By pulling metallized glass capillaries 120 slowly (˜1 cm/min) from bulk solution, they were coated with photoresist (Shipley 1813, Microlithography Chemical Corporation, Newton, Mass.) to form capillaries 122. Capillaries 122 were hard-baked at 105° C. for ˜3 min. Exposure (˜8 s) of the coated capillary to ultraviolet light (using a Karl Suss mask aligner) through a flexible mask [design shown in (C)] wrapped around its surface transferred an appropriate pattern into the photoresist to form capillaries 125. Under an optical microscope, two patterned capillaries 125 were aligned so that they were in close proximity to one another and their patterns matched to form a chain, as shown in FIG. 7(f). (Links correspond to openings in the photoresist. Dotted lines represent links on the undersides of the capillaries that are not visible from the top.) Electroplating nickel, from a nickel sulfamate-based plating bath (Technic, Providence, R.I., Techni-Nickel “S”) held at 45° C. for ˜30 min at a current density of 20 mA/cm², in areas defined by the photoresist electrochemically welded together the ends of the chain links. The freely jointed chain of FIG. 7(g) was released from the capillaries by dissolving the photoresist in acetone, the silver in an aqueous ferricyanide bath and the titanium and glass in concentrated HF.

### EXAMPLE 6

Described in this Example is a scheme for the formation of a trefoil knot of FIG. 8. Two designs of FIG. 8(a) were microcontact printed onto two silver-coated glass microcapillaries. After etching the unprotected silver and titanium, the two capillaries were aligned under a microscope so that their patterns were brought into register. The capillaries were glued in place an electrical connection was made followed by electroplating with nickel. During the plating step, the patterns became welded together. Extra connecting wires were removed with a pair of microscissors and the capillaries were dissolved in aqueous HF.

### EXAMPLE 7

The preparation of a 3-D truss is described in this Example. A design for truss patterns is generated using a suitable computer aided drawing (CAD) software application (Macromedia Freehand 7.0) printed onto a transparency using a commercial laser-assisted image-setting system (Hercules PRO, 3387 dpi, Linotype-Hell Company, Hauppauge, N.Y.). This transparency is used as a photomask to generate a relief pattern in a layer of photoresist. Microcontact printing is performed as described in FIG. 2. An elastomeric “stamp” is produced by molding this relief pattern in poly(dimethyl siloxane) (PDMS; Sylgard 184, Dow Corning, Midland, Mich.). The stamp, which carries the inverted relief pattern on one face, transfers a monomolecular pattern of a chemical “ink” to a substrate. In this case, the substrate consisted of a glass microscope slide coated with Ti (5 nm, adhesion promoter) and Ag (50 nm) using an e-beam evaporator. The ink is a 1 mM solution of hexadecanethiol (CH₃(CH₂)₁₅SH, “HDT”). HDT forms a self-assembled monolayer (SAM) on the surface of Ag that acts as a nanometer-thick resist to subsequent wet chemical etching. Immersion of the substrate in an aqueous ferricyanide solution (0.001 M K₄Fe(CN)₆, 0.01 M K₃Fe(CN)₆, and 0.1 M Na₂S₂O₃) for 20-30 s removed the underivatized areas of Ag; immersion in aqueous HF (1%) for 15-20 s removed the areas of Ti exposed by the ferricyanide etchant. The result was a supported pattern in Ag that precisely duplicated the pattern carried on the PDMS stamp.

After electrically contacting the silver pattern, the glass substrate is immersed in a Ag electroplating bath (Techni-Silver E2, Technic Inc., Providence, R.I.) at room temperature and electrodeposited Ag at a current density of ˜20 mA/cm² for 15 min. At this point, the adhesion between the electroplated Ag layer and the initial vapor-deposited Ag layer was sufficiently poor to make possible manual separation of the Ag grid structure from the substrate using tweezers.

As described previously, the 3-D truss can be thought of as an array of tetrahedra or as an array of square-based pyramids. The truss can also be assembled from its component set of grids, two of which are planar (grids 155 and 156 of FIG. 9) and one which is nonplanar (grid 153 of FIG. 9). The nonplanar grid 153 defines the edges of the triangular sides of the square-based pyramids in the array. The top and bottom square grids make up the bases of the inverted and upright pyramids, respectively, in the array. These are prepared by microcontact printing and electroplating as described above. The diagonal supports in each cell of the square grids add lateral stability to the structure by converting each square into two triangles. To make a 3-D grid, a 2-D grid pattern (grid 150 of FIG. 9) is first fabricated using microcontact printing on a planar substrate followed by electroplating. The grid 150 is then folded along dotted lines 154 using tweezers. Stamping of the folded grid with a machined brass die ensured the folds achieved the desired 70° angle.

The three grids are aligned manually as shown in FIG. 9(c) using a stereomicroscope to aid visualization. The grid sections measured ˜1 cm×2 cm, and each square cell measured ˜2 mm×2 mm. Application of silver paint to the outer corners of the grids (indicated by dashed lines) affixed the grids temporarily for the electroplating step. A Cu/Sn wire electrically contacted the structure. The truss is sandwiched between sections of glass microscope slides and the assembly is placed in a shallow Ni electroplating bath (Techni Nickel-S, Technic Inc., Providence, R.I.) held at 45° C. A 50 g weight placed onto the top glass slide applied pressure across the structure to ensure close contact between the grids during electroplating. After electroplating at a current density of ˜20 mA/cm² for 1 h, the weight and the glass slides are removed and the structure is electroplated at this current density for an additional 30 min to allow deposition on the top and bottom faces of the truss.

### EXAMPLE 8

The open framework of FIG. 11 is described in this example. The initial two-dimensional microstructure 160 of FIG. 11(a) is fabricated by microcontact printing of an alkanethiol on a silver-coated glass microscope slide using a suitable PDMS stamp followed by wet chemical etching in ferricyanide solution. An electroplated silver layer, formed in a similar manner as described in Example 7, strengthened the patterned thin film of metal, and the metallic 2-D object is mechanically separated from the glass substrate. The 2-D microstructure 160 is depicted as an array of triangular panels connected by a set of tabs 163 that form the hinges. The relative size of the hinges is exaggerated in this depiction, and the hinges have been omitted from subsequent sketches for clarity. Folding of the hinges along the indicated diagonal axes (FIG. 11(b)) results in the hemicylindrical object. Further folding along the indicated axes parallel to the long axis of the hemicylindrical object forms the final arch (FIG. 11(c)). A final electroplating step with Ni, as directed previously, reinforces the structure and fixes the hinge positions.

Those skilled in the art would readily appreciate that all parameters listed herein are meant to be examples and that actual parameters will depend upon the specific application for which the methods and apparatus of the present invention are used. It is, therefore, to be understood that the foregoing embodiments are presented by way of example only and that, within the scope of the appended claims and equivalents thereto, the invention may be practiced otherwise than as specifically described.

1. A method for making a three-dimensional microstructure, comprising deforming a first microstructure at a predetermined deformable portion.

2. A method as in claim 1, wherein the deforming comprises bending.

3. A method as in claim 1, wherein the deformable portion allows deformation in a predetermined direction.

4. A method as in claim 1, wherein the deformable portion allows deformation to a predetermined angle.

5. The method of claim 1, wherein the deformable portion comprises thinner dimensions than regions immediately adjacent the deformable portion.

6. A method as in claim 1, wherein the first microstructure is two-dimensional.

7. A method as in claim 1, wherein the first microstructure is three-dimensional.

8. A method as in claim 1, wherein the three-dimensional microstructure has at least one component with at least one dimension less than about 1 mm.

9. A method as in claim 8, wherein the three-dimensional microstructure has at least one dimension less than about 500 μm.

10. A method as in claim 9, wherein the three-dimensional microstructure has at least one dimension less than about 100 μm.

11. A method as in claim 10, wherein the three-dimensional microstructure has at least one dimension less than about 25 μm.

12. A method as in claim 1, wherein the first microstructure further comprises rigid portions unaffected by the deforming step.

13. A method as in claim 1, wherein the deformable portion has a thinner dimension than an adjacent portion.

14. A method as in claim 1, wherein the deformable portion comprises a discontinuous pattern.

15. A method as in claim 1, further comprising reinforcing the three-dimensional microstructure after deforming.

16. The method of claim 15, wherein the reinforcing comprises electroplating.

17. A method as in claim 16, wherein the electroplating increases a thickness of at least a portion of the three-dimensional microstructure by at least 10%.

18. A method as in claim 1, comprising connecting the first microstructure to a second microstructure, wherein the first microstructure is integral with the second microstructure in the 3-dimensional microstructure.

19. A method as in claim 18, wherein the connecting step comprises positioning a portion of the first microstructure adjacent a portion of the second microstructure and electroplating the positioned first and second microstructures.

20. A method for making a three-dimensional microstructure, comprising:
deforming a microstructure at a predetermined deformable portion to provide a deformed portion;
treating the deformed portion to form a non-deformable portion.

21. A method as in claim 20, wherein the treating comprises electroplating the deformed portion.

22. A method for making a three-dimensional microstructure, comprising:
providing a microstructure;
deforming a portion of the microstructure in a first predetermined orientation to form a deformed portion;
treating the deformed portion; and
applying a deformation to a portion of the microstructure in a second predetermined orientation.

23. A method as in claim 22, wherein the first predetermined orientation comprises a predetermined direction.

24. A method as in claim 22, wherein the first predetermined orientation comprises a predetermined angle.

25. A method for making a microstructure having a link, comprising:
providing a first and a second three-dimensional substrate;
printing a pattern on the first and second substrates;
supporting the first substrate adjacent the second substrate to provide a combined pattern having at least one feature resembling a link;

26. The method of claim 25, wherein the link comprises a chain link.

27. The method of claim 25, further comprising reinforcing the supported first and second substrates.

28. The method of claim 27, further comprising dissolving the first and second substrates.

29. A free-standing, integral three-dimensional truss.

30. A truss as in claim 29, wherein the truss is a microstructure.

31. A truss as in claim 29, wherein the truss has at least one dimension less than about 1 mm.

32. A truss as in claim 29, wherein the truss comprises at least two tetrahedra placed side-by-side.

33. A truss as in claim 32, wherein the truss comprises at least two square pyramids placed side-by-side.
